(19) United States
(12) Patent Application Publication
(10) Pub. No.: US 2006/0051681 A1
(43) Pub. Date: Mar. 9, 2006

(54) Method of repairing a photomask having an internal etch stop layer

(75) Inventor: Darren T. Taylor, The Colony, TX (US)

Correspondence Address: AMSTER, ROTHSTEIN & EBENSTEIN LLP, 90 PARK AVENUE, NEW YORK, NY, 10016, US

(73) Assignee: PHOTOTRONICS, INC. 15 SECOR ROAD P.O. BOX 5226 BROOKFIELD, CONECTICUT

(21) Appl. No.: 10/936,071

(22) Filed: Sep. 8, 2004

(51) Int. Cl. G03C 5/00; G03F 1/00

(52) U.S. Cl. 430/5; 430/322; 430/30; 430/323; 430/324

(57) ABSTRACT

A method of repairing a photomask having a pattern layer, an internal etch stop layer underlying the pattern layer and a substantially transparent substrate. After the mask has been partially or fully processed, the mask is inspected for defects. Defects which are appropriate to be repaired are identified, and openings associated with each defect are written into jobdeck instructions. A new layer of photoresist material is then deposited on the photomask after cleansing, and openings associated with each defect to be repaired are written into the new layer of photoresist. After the openings are developed and rinsed so that the defects to be repaired are exposed, the photomask is again etched to remove the exposed defects. Since there is an etch stop layer underlying the defects in the exposed areas, only the defect is removed and no further damage is caused to the photomask. The photoresist may then be removed, and the photomask may then be inspected to insure that the defects have been sufficiently repaired. Further processing of the photomask may then continue in the usual manner.

### FIELD OF THE INVENTION

The present invention generally relates to optical lithography and more particularly relates to improved photomasks, including binary photomasks, embedded attenuated phase shift masks (“eaPSMs”), alternating aperture phase shift masks (“aaPSMs”), and methods of making the same. More particularly, the present invention relates to a system and method for repairing defects on a photomask having an internal etch stop layer and a layer deposited thereon which has been partially or fully processed.

### BACKGROUND OF THE INVENTION

Photomasks are high precision plates containing microscopic images of electronic circuits. Photomasks are typically made from flat pieces of material that are substantially transparent, such as quartz or glass, with an opaque layer, such as chrome, on one side. Etched in the opaque layer (e.g., chrome) of the mask is a pattern corresponding to a portion of an electronic circuit design. A variety of different photomasks, including for example, aaPSMs, embedded attenuated phase shift masks and binary photomasks (e.g., chrome-on-glass), are used in semiconductor processing to transfer these patterns onto a semiconductor wafer or other type of wafer. These and other kinds of photomasks, such as, e.g., binary half tone photomasks, such as described in co-pending U.S. Patent Publ. No. 2003-0138706-A1, which is hereby incorporated by reference herein in its entirety, are also used to make other kinds of devices.

As shown in FIGS. 1a and 1b, to create an image on a semiconductor wafer 20, a photomask 9 is interposed between the semiconductor wafer 20 (which includes a layer of photosensitive material) and an optical system 22. Energy generated by an energy source 23, commonly referred to as a Stepper, is inhibited from passing through opaque areas of the photomask 9. Likewise, energy from the Stepper passes through the substantially transparent portions of the photomask 9, thereby projecting a diffraction limited, latent image of the pattern on the photomask onto the semiconductor wafer 20. In this regard, the energy generated by the Stepper causes a reaction in the photosensitive material on the semiconductor wafer such that the solubility of the photosensitive material is changed in areas exposed to the energy. Thereafter, the soluble photosensitive material (either exposed or unexposed) is removed from the semiconductor wafer 20, depending upon the type of photolithographic process being used. For example, where a positive photolithographic process is implemented, the exposed photosensitive material becomes soluble and is removed. By contrast, where a negative photolithographic process is used, the exposed photosensitive material becomes insoluble and the unexposed, soluble photosensitive material is removed. After the appropriate photosensitive material is removed, a pattern corresponding to the photomask 9 appears on the semiconductor wafer 20. Thereafter, the semiconductor wafer 20 can be used for deposition, etching, and/or ion implantation processes in any combination to form an integrated circuit.

As circuit designs have become increasingly complex, semiconductor manufacturing processes have become more sophisticated to meet the requirements of these complexities. In this regard, devices on semiconductor wafers have continued to shrink while circuit densities have continued to increase. This has resulted in an increased use of devices packed with smaller feature sizes, narrower widths and decreased spacing between interconnecting lines. For photolithographic processes, resolution and depth of focus (DoF) are important parameters in obtaining high fidelity of pattern reproduction from a photomask to a wafer. However, as feature sizes continue to decrease, the devices' sensitivity to the varying exposure tool wavelengths (e.g., 248 nm, 193 nm, 157 nm, 13 nm, etc.) used to write images on a semiconductor wafer has increased, thereby making it more and more difficult to write to an accurate image on the semiconductor wafer. In this regard, as feature sizes continue to decrease, light diffraction effects in the photomask are exacerbated, thereby increasing the likelihood that defects will manifest in a pattern written on a semiconductor wafer. Accordingly, it has become necessary to develop new methods to minimize the problems associated with these smaller feature sizes.

One known method for increasing resolution in smaller feature sizes involves the use of shorter exposure wavelengths (e.g., 248 nm, 193 nm, 157 nm, 13 nm, etc.). Shorter exposure wavelengths, however, typically result in a shallower DoF in conventional binary chrome-on-glass (COG) photomasks having smaller feature sizes. In this regard, when the feature size is smaller than the exposure tool wavelength, binary COG photomasks become diffraction limited, thereby making it difficult, if not impossible, to write an accurate image on the semiconductor wafer. Accordingly, phase shifting masks (“PSMs”) have been used to overcome this problem. In this regard, PSMs are known to have properties which permit high resolution while maintaining a sufficient DoF. More particularly, a PSM reduces the diffraction limitation ordinarily associated with a binary COG mask by passing light through substantially transparent areas (e.g., glass, quartz or fused silica) which have either different thickness and/or different refractive indices than an ordinary binary COG mask. As a result, destructive interference is created in regions on the target semiconductor wafer that are designed to see no exposure. Thus, by reducing the impact of diffraction through phase shifting, the overall printability of an image is vastly improved such that the minimum width of a pattern resolved by using a PSM is approximately half the width of a pattern resolved in using an ordinary binary COG mask.

Various types of PSMs have been developed and are known in the art, including aaPSMs as described in U.S. Patent Publ. No. 2004-0086787 A1, and U.S. patent application Ser. No. 10/391,001 filed Mar. 18, 2003, which are incorporated by reference herein in their entirety. FIGS. 2a-b illustrate an example of a conventional aaPSM 10. An aaPSM is typically comprised of a layer of opaque material and a substantially transparent substrate which is etched on one side of the opaque features, while not etched on the other side (e.g., etching of the transparent substrate occurs in alternating locations in the substantially transparent substrate). More particularly, as shown in FIGS. 2a-b, the aaPSM 10 includes a substantially transparent layer 13 (e.g., glass, quartz or fused silica) and an opaque layer (e.g., chrome). The opaque layer is etched to form opaque regions 15 and alternating substantially transparent regions 13, as shown in FIG. 2b. The substantially transparent regions 13 are further etched such that the aaPSM 10 has recesses 14 in the substantially transparent layer. In other words, the aaPSM 10 has substantially transparent regions 13 (which are un-etched) that alternate with etched recesses 14 between each opaque region 15, as shown in FIGS. 2a-b. The effect of this structure when placed in a Stepper is to create light intensity of alternating polarity and 180° out of phase, as shown in FIG. 2c. This alternating polarity forces energy transmitted from the Stepper to go to zero, in theory, at opaque regions 15 while maintaining the same transmission of light at the alternating transparent regions 13 and recesses 14. As a result, refraction is reduced through this region. In this regard, in recesses 14, equation (1) is satisfied:
d=λ/2(n−1) (1)
where d is film thickness, n is refractive index at exposure wavelength, λ is exposure wavelength. Thus, it is possible to etch smaller features in a semiconductor wafer and use shorter exposure wavelengths. Since the photoresist layer on the semiconductor wafer (FIG. 2d) is insensitive to the phase of the exposed light, the positive and negative exposed regions appear the same, while the zero region in between is clearly delineated. Thus, a sharper contrast between light (e.g., transparent) and dark (e.g., opaque) regions in the resulting photoresist layer of a semiconductor is obtained, thereby making it possible, in theory, to etch a more accurate image onto the semiconductor wafer.

In practice, however, it is difficult to ensure as the size of aaPSM continue to get smaller that the etched trenches are formed accurately. Conventional processes used to make aaPSMs etch the photomask to a specific depth which is determined by the wavelength of radiation used, as discussed above. Since this depth is significantly less than the photomask substrate thickness, there is no known technique where an optical emission spectrum (OES) could be used to determine the exact and appropriate etch time needed. In addition, there is no additional etching step (referred to as “overetch”) that can be done to address the plasma non-uniformity. Thus, there has been a long felt need for end point detection methods using an OES technique which allows for additional overetch time to adjust for any non-uniformities associated with plasma loading effects due to pattern density on the photomask.

To address this need, various attempts have been made to disclose a photomask having an internal etch stop layer. For example, co-pending U.S. patent application Ser. No. 10/658,039, filed on Sep. 9, 2003, assigned to the same assignee, and its continuation-in-part U.S. patent application Ser. No. ______, filed on Sep. 8, 2004, entitled “Photomask Having Internal Substantially Transparent Etch Stop Layer”, assigned to the same assignee, which are hereby incorporated by reference in their entirety, discloses the use of a substantially transparent etch stop layer such as MgFₓ, MgF₂, AlₓO_{y}, Al₂O₃. Others, such as U.S. Patent Publ. No. 2004/0137335 A1, and U.S. Pat. No. 6,730,445, which are also incorporated by reference in their entirety, have disclosed the use of other materials including chromium or other material, such as, CrN, CrC, CrO, Ta, TaN, TaNO, TaO, W (and its oxides), and Mg (and its oxides), as well as a metal or metal based layer, like Ta and Ti, which can be used as an internal etch stop in a photomask. However, none of these references teach that an etch stop layer can be used to make repairs to remove a defect using another etching step.

To compound these problems, after a patterned layer has been formed on the photomask during processing, it may have defects on the substantially transparent layer (e.g., quartz) or on other layers. A defect is any flaw affecting the geometry of the pattern design. For example, a defect may result when chrome is located on portions of the EAPSM 10 where it should not be (e.g., chrome spots, chrome extensions, or chrome bridging between geometry) or unwanted clear areas (e.g., pin holes, clear extensions, or clear breaks). A defect in an aaPSM can cause a semiconductor to function improperly. To avoid improper function, a semiconductor manufacturer will typically indicate to a photomask manufacturer the size of defects that are unacceptable. All defects of the indicated size (and larger) must be repaired. If such defects cannot be repaired, the mask must be rejected and rewritten.

To determine if there are any unacceptable defects in a particular photomask, it is necessary to inspect the photomask. Typically, automated mask inspection systems, such as those manufactured by KLA-Tencor, ETEC (an Applied Materials company), NEC and Lastertech, are used to detect defects. Inspection tools use light transmitted through the aaPSM to find defects in a pattern. In this regard, automated inspection systems direct an illumination beam at the photomask and detect the intensity of the portion of the light beam transmitted through and reflected back from the photomask. The detected light intensity is then compared with expected light intensity, and any deviation is noted as a defect. In this regard, the inspection tool compares the patterned data on the mask to either another part of the mask or to expected pattern data stored in a database. The details of one inspection system can be found in U.S. Pat. No. 5,563,702, assigned to KLA-Tencor. Current inspection equipment is manufactured to operate at wavelengths between the ranges of 365 nm and 193 nm. Examples of such inspection systems include the KLA-Tencor SLF 77 and AMAT ARIS21-I.

Once identified, defects are typically removed mechanically (e.g., by scrubbing it off) or by a combination of topographically mapping the defect and removing the defect through focused ion beam (FIB) milling. Mechanical removal tools can micro-chisel defects from a photomask, but are considerably expensive. Additionally, while FIB is somewhat effective in removing defects, the FIB equipment often emits gallium which can become implanted on the photomask being repaired, which in turn, can change the transmission properties of the photomask in such regions. These techniques are expensive, time consuming and cumbersome, and often result in an increased cycle-time to manufacture a photomask. Thus, there is a long felt need for a method and system which removes defects from aaPSMs and other types of photomasks in a more efficient manner.

After inspection is completed (albeit with unsatisfactory results), a completed photomask is cleaned of contaminants. The cleansing process can also affect the quality of the photomask. Next, a pellicle may be applied to the completed aaPSM to protect its critical pattern region from airborne contamination. Subsequent through pellicle defect inspection may be performed. After these steps are completed, the completed aaPSM is used to manufacture semiconductors and other products. The same types of manufacturing processes are used to manufacture other types of photomask as is well known in the art.

Accordingly, it is object of the present invention to provide a system and method for efficiently removing defects from partially or fully processed aaPSMs and other types of photomasks.

It is yet another object of the present invention to provide a system and method for removing defects from partially or fully processed aaPSMs and other types of photomasks that does not effect the transmission properties of the photomask.

It is yet another object of the present invention to provide software for facilitating the disclosed defect removal process.

It is another object of the present invention to solve the shortcomings of the prior art.

Other objects will become apparent from the foregoing description.

### SUMMARY OF THE INVENTION

It has now been found that the above and related objects of the present invention are obtained in the form of a photomask, such as an aaPSM, having an internal etch stop layer and at least one deposited layer formed thereon. The deposited layer may be either a deposited substantially transparent layer, such as SiO₂, a deposited partially transparent layer, such as MoSi, or a deposited opaque layer, such as Cr. The internal etch stop layer of the present invention may be either substantially transparent, in which case it may remain on the blank although the additional layers will be removed to form a patterned photomask, or may be not transparent, in which case it will need to be removed in exposed areas after the pattern in the layers above it have been formed. Examples of materials which can be used as an etch stop layer include, MgFₓ, MgF₂, AlₓO_{y}, Al₂O₃, AlN, AlF, CaF, LiF, SiO₂, SiₓN_{y}, materials including chromium or other material, such as, CrN, CrC, CrO, Ta, TaN, TaNO, TaO, Ta₂O₅, Y₂O₃, ZrO, W (and its oxides), and Mg (and its oxides), as well as a metal or metal based layer, like Ta and Ti. In a preferred embodiment, the internal substantially transparent etch stop layer of the present invention is comprised of MgFₓ and even more particularly is comprised of MgF₂ deposited under evaporation. Other materials that may be used for the substantially transparent etch stop layer of the present invention include, but are not limited to, Al₂O₃ and AlₓN_{y}.

The present invention is also directed to a method and system for processing a photomask, such as an aaPSM, and removing defects from the same. More particularly, after the photomask of the present invention has been etched to form a pattern in the deposited layer on the etch stop layer, the photomask is inspected for defects, such as chrome spots, chrome extensions or chrome bridging between gaps in etched regions of the mask, phase bumps or phase edge bumps. An inspection file is generated using conventional inspection equipment, and thereafter, this file is analyzed to note the location and size of the defects, among other things. The inspection file is typically in the format of a text file, but may be in any suitable format. Based on this information, a repair file (e.g., jobdeck instructions) is written into the exposure tool which allows the exposure tool to isolate the defect during developing. The photomask is then re-coated with photoresist and the exposure tool etches away the defect in accordance with the jobdeck instructions. In this regard, the jobdeck instructions cause the exposure tool to develop an open window in the photoresist layer which exposes only the defect in the photomask. If more than one defect is located by the inspection file, then a corresponding window for each defect to be removed is created. The defect is then removed by standard etching techniques, such as wet etching, dry etching or etching known to those of skill in the art. Since there is an etch stop layer underneath the exposed defect, the etching will remove the defect but not cause any further damage to the exposed portion of the photomask. If desired, the etch stop layer may be removed in areas where the pattern is not located, or in the case of a substantially transparent etch stop layer may be left alone. Thereafter, processing of the photomask is completed.

Additionally, the present invention is directed to a method for manufacturing a semiconductor comprising the steps of: interposing a processed photomask of the present invention (which has had at least one defect removed in accordance with the system and method of the present invention) between a semiconductor wafer and an energy source, wherein the photomask comprises an patterned opaque layer with a first set of at least one light transmitting openings and a second set of at least one light transmitting openings; a deposited substantially transparent layer underlying the opaque layer wherein the deposited substantially transparent layer has corresponding light transmitting openings to each of the openings of the first set of at least one light transmitting openings, a substantially transparent etch stop layer underlying the deposited substantially transparent layer, and a substantially transparent substrate underlying the substantially transparent etch stop layer. The method further comprises the steps of generating energy in the energy source; transmitting the generated energy through the first and second set of at least one light transmitting openings; and etching an image on the semiconductor wafer corresponding to a pattern formed by the first and second set of at least one light transmitting openings.

### BRIEF DESCRIPTION OF THE DRAWINGS

The above and related objects, features and advantages of the present invention will be more fully understood by reference to the following, detailed description of the preferred, albeit illustrative, embodiment of the present invention when taken in conjunction with the accompanying figures, wherein:

FIG. 1a shows the equipment which can be used to make a semiconductor device from a photomask;

FIG. 1b is flow diagram showing an example of the process for making a semiconductor device;

FIG. 2a shows a plan view of a conventional aaPSM;

FIG. 2b shows a cross-sectional view of conventional aaPSM;

FIG. 2c shows the light intensity transmitted through the aaPSM of FIGS. 2a-b;

FIG. 2d is a semiconductor wafer exposed to light transmitted through the aaPSM of FIGS. 2a-b;

FIG. 3 shows a cross-sectional view of a photomask blank having an internal etch stop layer;

FIGS. 4A and 4B are SEM images, at different magnifications, of an isolated 180° phase bump defect in a processed aaPSM;

FIGS. 5A and 5B are SNP images of the isolated phase bump shown in FIGS. 4A and 4B;

FIG. 6 is SEM image of an isolated 180° edge phase bump defect in a processed aaPSM;

FIGS. 7A and 7B are SNP images of the edge phase bump defect shown in FIG. 6;

FIG. 8 is a data image showing an open window to developed around the phase bump defect shown in FIGS. 4A, 4B, 5A, and 5B in accordance with the system and method of the present invention;

FIG. 9 is a data image showing an open window to be developed around the edge phase bump defect shown in FIGS. 6, 7A and 7B in accordance with the system and method of the present invention;

FIG. 10 is an SEM image of the aaPSM shown in FIGS. 4A, 4B, 5A and 5B after the phase bump defect has been removed in accordance with the system and method of the present invention;

FIGS. 11A and 11B are SNP images of the aaPSM shown in FIGS. 4A, 4B, 5A and 5B after the phase bump defect has been removed;

FIG. 12 is an SEM image of the aaPSM shown in FIGS. 6, 7A and 7B after the edge phase bump defect has been removed in accordance with the system and method of the present invention;

FIGS. 13A and 13B are SNP images of the aaPSM shown in FIGS. 6, 7A and 7B after the edge phase bump defect has been removed in accordance with the system and method of the present invention;

FIG. 14A is an aerial image of the aaPSM shown in FIGS. 4A, 4B, 5A and 5B;

FIG. 14B is an aerial image of the aaPSM shown in FIGS. 4A, 4B, 5A and 5B after the phase bump defect has been removed in accordance with the system and method of the present invention;

FIG. 15 is an intensity profile of the aaPSMs shown in FIGS. 14A and 14B which was taken using a Zeiss AIMSfab 193 nm tool; and

FIGS. 16A and 16B are SNP and SEM images, respectively, of a second embodiment of the present invention where a defect was removed using a 450° overetch in accordance with the system and method of the present invention.

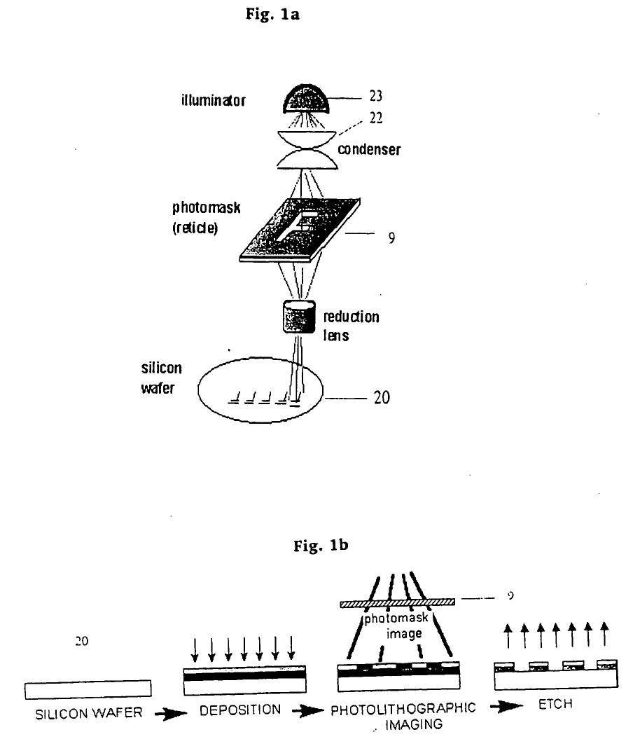

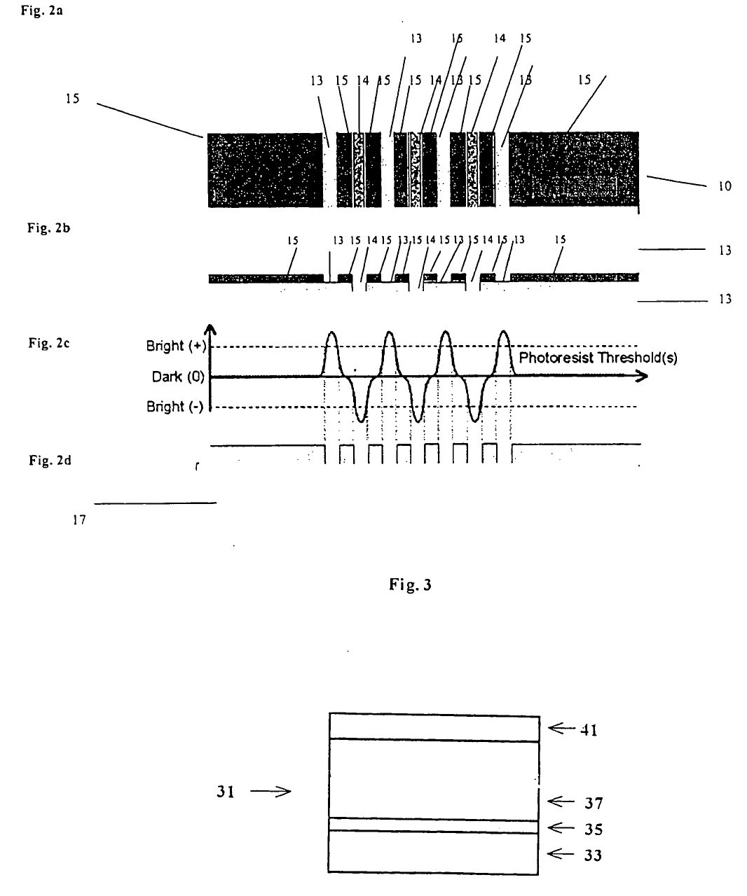

### DETAILED DESCRIPTION OF THE PREFERRED EMBODIMENTS

The present invention is directed to a method for removing defects from a photomask after it has been partially or fully processed. The photomask used in conjunction with the method of the present invention includes an etch stop layer disposed between a substantially transparent substrate and a pattern layer having a pattern formed therein during photomask processing to ensure that a trench in said pattern layer is etched to a proper depth during processing of the photomask. In a preferred embodiment, the etch stop layer is substantially transparent, but in other embodiments, need not be transparent. The etch stop layer can be used in a broad variety of types of photomasks which require etching of layers of materials to a particular specific depth, including, for example, binary photomasks such as chrome-on-glass photomasks, phase shift masks, such as embedded attenuated phase shift masks (“eaPSMs”), and attenuated phase shift masks (“aaPSMs”), as well as binary half-tone masks or other types of gray scale photomasks. Moreover, the internal substantially transparent etch stop layer of the present invention can have additional layers deposited thereon, such as a hard mask layer to prevent macroloading effects as disclosed in U.S. Pat. Nos. 6,472,107, 6,682,861 and 6,749,974, to the same assignee, which are hereby incorporated by reference in their entirety, or an intermediate inspection layer such as described in U.S. Patent Publication No. 2004/0043303, assigned to the same assignee, which is hereby incorporated by reference in its entirety.

In particular, the method of the present invention relates to the removal of defects from the photomask having an etch stop layer under a pattern layer after the pattern has been formed. More particularly, after the photomask has been etched, the photomask is inspected for defects, such as in the case of binary masks containing a chrome pattern layer, chrome spots, chrome extensions or chrome bridges between gaps in etched regions, or as in the case of the phase shift mask, phase bumps or phase edge bumps. An inspection file is generated using conventional inspection equipment, and thereafter, this file is analyzed to identify the location and size of the defects, among other things. Based on this information, a repair file (e.g., jobdeck instructions) is written into the exposure tool which allows the exposure tool to isolate the defect during developing. The repair file will identify an opening to be formed in a new photoresist layer around each defect identified to be removed by further etching. The photomask is then re-coated with photoresist, and openings are written into the photoresist based on the instruction contained in the repair file. In this regard, the jobdeck instructions cause the exposure tool to develop an open window in the photoresist layer for each defect identified to be removed which exposes the associated defect in the photomask. The defect is then removed by standard etching techniques applicable for the particular material in question, such as wet etching or dry etching as known to those of skill in the art, and the photoresist is then removed using conventional techniques. Thereafter, processing of the photomask is completed.

The photomask to be used with the method of the present invention is first described, and thereafter, the method and system for removing defects for this photomask after it has been partially or fully processed is described.

Turning first to the photomask, as noted above a wide variety of types of photomask can be used in conjunction with the method and system of the present invention. For example, the present invention may apply to traditional binary masks, phase shift masks and even binary half tone masks. A key aspect with respect to the photomask however is that the photomask is comprised of at least three layers: a pattern layer in which a pattern is to be formed, an etch stop layer underlying the pattern layer and a substantially transparent substrate underlying the etch stop layer. For purposes of illustrating the present invention, an example describing an aaPSM is provided.

More particularly, referring to FIG. 3, a blank photomask 31 made in accordance with the present invention is shown. The blank photomask 31 preferably includes at least four layers, but may include additional layers as needed or desired by the photomask manufacturer. For example, it may include a hard mask layer such as described in U.S. Pat. Nos. 6,472,107, 6,682,861 and 6,749,974, which are incorporated by reference herein in their entirety. Similarly, the blank photomask may include, for example, an inspection layer such as described in U.S. Patent Publ. No. 2004/0043303 A1, to the same assignee, which is also incorporated by reference herein. These two examples of other potential layers that can be used in accordance with the present invention are merely illustrative and by no means intended to limit the scope of the present invention. In particular, the four layers include:
a. First, a substantially transparent layer 33, such as quartz, glass or fused silica.
b. Second, an etch stop layer 35. Examples of materials which can be used as an etch stop layer include, MgFₓ, MgF₂, AlₓO_{y}, Al₂O₃, AlN, AlF, CaF, LiF, SiO₂, SiₓN_{y}, materials including chromium or other material, such as, CrN, CrC, CrO, Ta, TaN, TaNO, TaO, Ta₂O₅, Y₂O₃, ZrO, W (and its oxides), and Mg (and its oxides), as well as a metal or metal based layer, like Ta and Ti. In a preferred embodiment, the etch stop layer is substantially transparent and may be comprised of MgFₓ and even more particularly is comprised of MgF₂ deposited under evaporation. Other materials that may be used for the substantially transparent etch stop layer include, but are not limited to, Al₂O₃ and AlₓN_{y}. In selecting the material and thickness of the substantially transparent etch stop layer and the deposited substantially transparent layer of the present invention, the factors set forth in U.S. patent application Ser. No. 10/658,039, filed on Sep. 9, 2003, which application is hereby incorporated by reference herein in its entirety, should be considered.
c. Third, a pattern layer 37 in which a pattern is to be formed. In the case of a binary mask, layer 37 would be an opaque layer (e.g., chrome), capable of absorbing all (or most) light to which it is exposed. Other available opaque materials known to those of skill in the art, such as Ta, Ti, W, Al, Silicon, for example, may alternatively be used. In the case of a binary photomask, the opaque layer 37 may additionally include an anti-reflective layer, such as chrome oxide, chrome oxy-nitride, chrome nitride, or glassy substance such as SiO₂, SiON, having a thickness of the wavelength divided by four, if desired or needed. In the case of an aaPSM, layer 37 would comprise a deposited substantially transparent layer 37, preferably having a thickness of λ/2(n−1). The deposited substantially transparent layer 37 is preferably comprised of SiO₂, but may be comprised of other materials that are not substantially transparent at the exposure wavelengths. For example, although not preferred, SiON could be used which has a higher extinction coefficient “k” and transmits a majority of the light to act as a phase shift material. Alternatively, in the case of a phase shift mask, instead of an opaque layer 37, a phase shift layer 37 may be used. In a preferred embodiment, phase shift layer 37 is comprised of a phase shifting material such as MoSi, TaSiO, TaSiON, or others as are well known in the art.
d. Fourth, a photoresist layer 41 comprised of photosensitive material. Examples of suitable photosensitive materials include Fuji FEB171 CAR, Fuji FEN270, Sumitomo IP3500, Sumitomo IP3600, or others as are well known in the art.

In the above embodiments of the present invention, the blank photomask can be processed as discussed in any appropriate manner such that during processing, the etch stop layer will act as an etch stop of the pattern layer. Once the photomask has been partially or fully processed, it is inspected for defects which are then removed in accordance with the system and method of the present invention.

More particularly, after the photomask has been partially or fully etched, it is inspected for defects, such as in the case of binary masks having a pattern layer comprised of chrome, chrome spots, chrome extensions or chrome fill gaps, or in the case of a psm, defects such as phase bump defects and edge phase bump defects, to name a few. In this regard, the processed photomask is inspected with standard inspection equipment, such as the KLA-Tencor SLF or KLA-Tencor 576, that is capable of detecting these types of defects. Using this inspection equipment (or other appropriate inspection equipment as known to those of skill in the art), an inspection file is generated. The inspection file should include information that identifies any defects in the processed photomask, including the size and coordinates of the defect (e.g., a defect file such as a KLA KLARF file), as well as other information, such as the coordinates of the reference marks used to carry out the inspection. This information is then analyzed and a repair file is written as a “jobdeck”. Jobdeck processing is well known in the art and typically refers to the method by which instructions are transferred to and processed by lithography tools (e.g., E-beam and laser beam) and inspection equipment (e.g., KLA or Orbot). In the present invention, jobdeck instructions are programmed into the exposure tool which specify which of the defects that were identified during inspection should be removed, and include instructions as to how to remove such defects. In this regard, the jobdeck instructions specify the location of the defect on the photomask, the size of the defect, the etching parameters used to remove the defect. Based on these instructions, it will be possible for the exposure tool to isolate the defect only such that the defect can be etched away after exposure without causing further etching in other regions of the photomask. The jobdeck instructions will identify a window to be formed in photoresist which surrounds each defect identified for removal. Optionally, a topographical map of the defect can be generated for further analysis, if desired.

Next, the partially or fully processed photomask may be cleaned using conventional techniques and is then coated with photoresist. The exposure tool then exposes the portions of the photoresist as specified in the jobdeck. In other words, the jobdeck causes the exposure tool to expose areas of photoresist which correspond to the location of the defects identified to be removed. By doing so, an “open window” is created in the photoresist layer which exposes the defect for further processing. Thereafter, the defect is etched away using the same type of etching techniques that was originally used to process to form the pattern in the pattern layer in the first place. Of course, it is also possible to remove the defect by other known etching techniques. Since there is an etch stop layer underlying the exposed area of the photomask, and the photoresist coating the remainder of the photomask, the etching process should only remove the defect and not cause any further damage to the photomask. If desired, for quality control purposes, the area where the defect was removed can be further inspected to ensure that it has been adequately removed. This can be done using AIM hardware simulation or other similar known techniques. Standard processing of the photomask should then be resumed after the defect has been removed.

### EXAMPLES

### Example 1

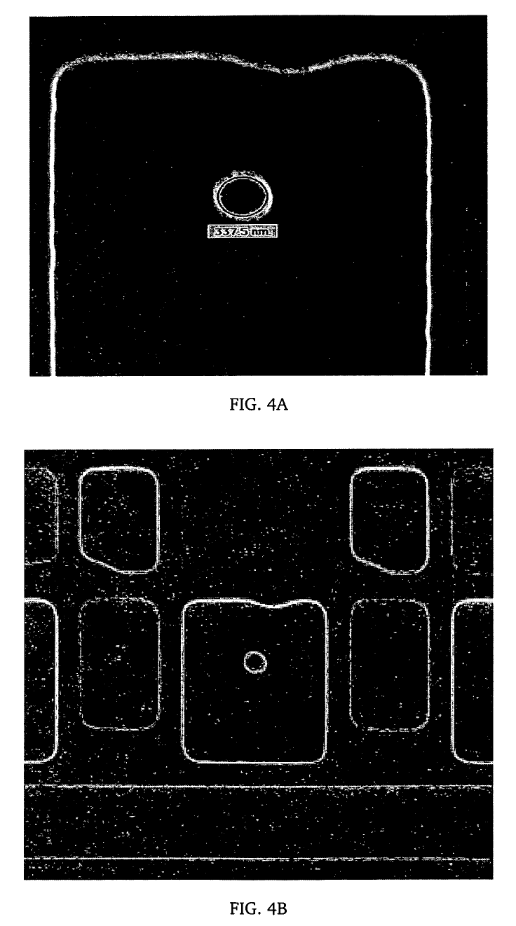

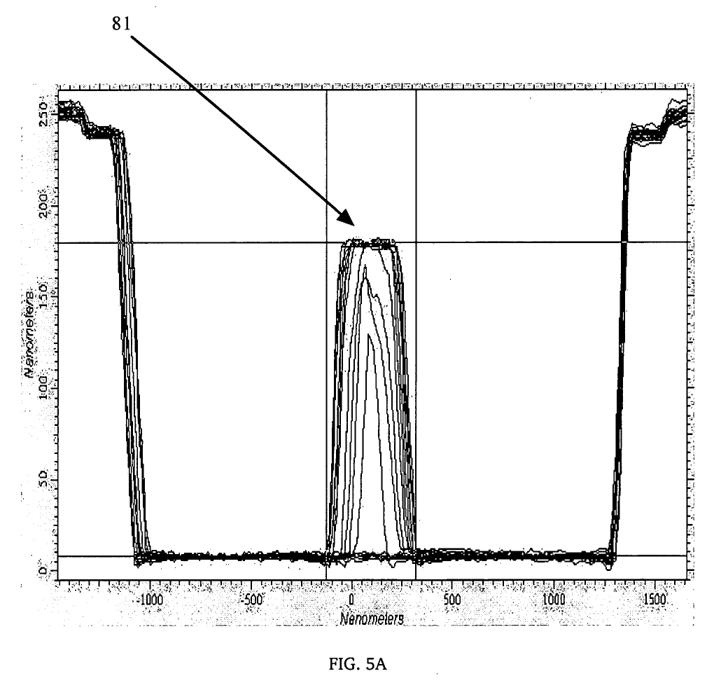

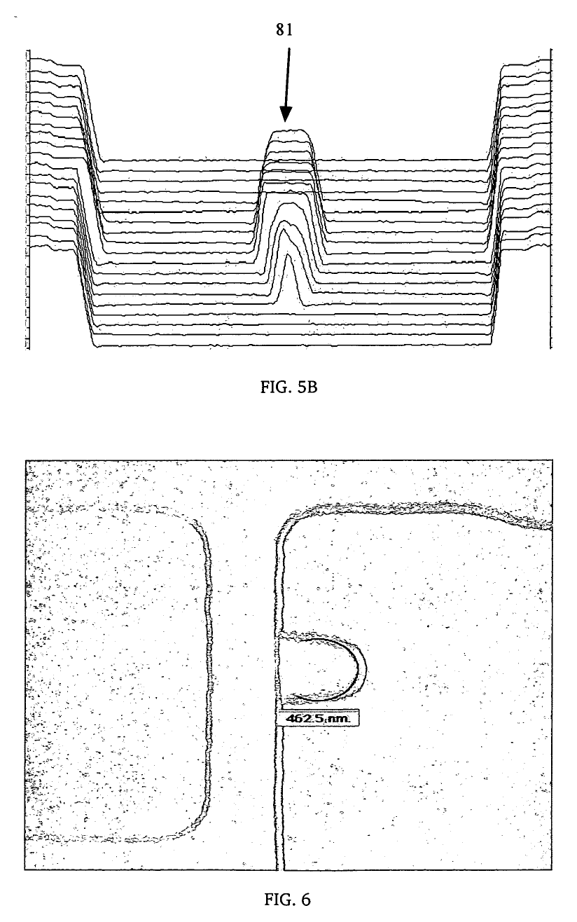

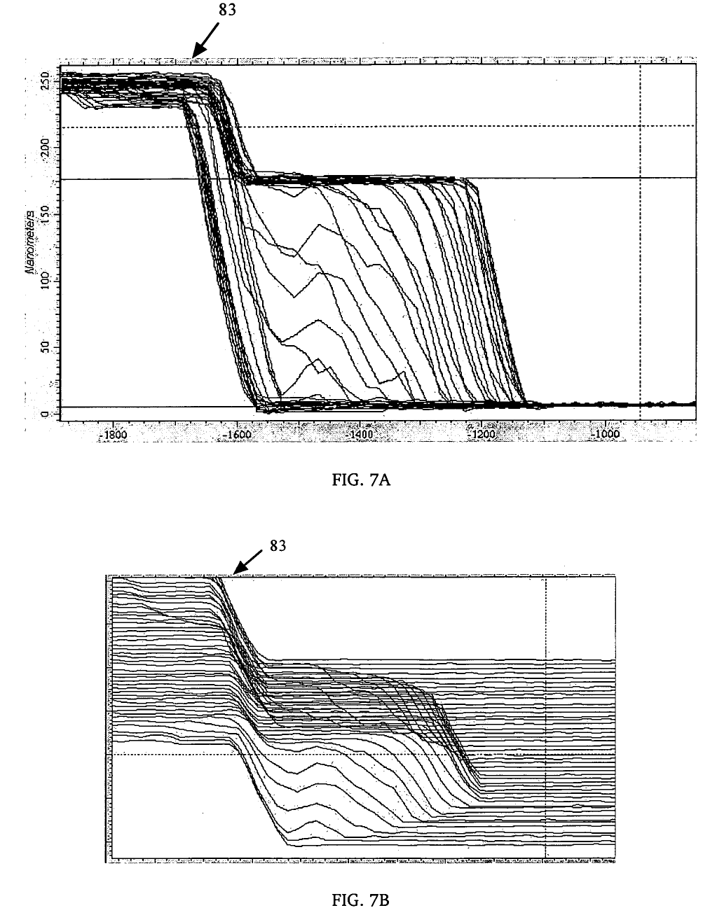

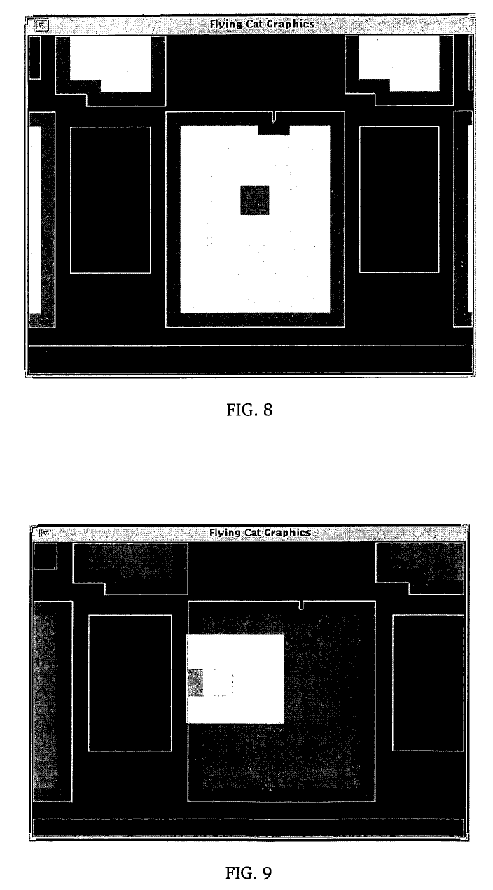

In accordance with the present invention, an aaPSM having a substantially transparent layer was processed using conventional dry etching techniques with an overetch of 10%. The pattern to be etched was designed to have phase bump defects. The processed aaPSM was inspected for defects on a KLA-Tencor SLF87 and a KLARF file was created. Defects were then selected for repair. In this experiment, the defects selected were an isolated 180° phase bump defect 81, as shown in the SEM images and SNP images of FIGS. 4A, 4B, 5A and 5B, respectively, and a 180° edge phase bump defect 83, as shown in the SEM image and SNP images of FIGS. 6, 7A and 7B, respectively.

Thereafter, a jobdeck file was programmed based on pertinent data relating to the phase bump defect, including its size and location, as well as the coordinates of the reference mark used for inspection. Several defect sites were selected showing different defect types. SEMs were taken of each site showing the phase defect. A FEI SNP9000, a scanning probe metrology tool, was used to generate topographical scans of each defect location. The aaPSM was then cleaned and coated with photoresist using standard processes. Thereafter, the exposure tool was used to expose areas in the photoresist as specified by the jobdeck instructions. The exposed photoresist was removed from the aaPSM to create open windows around the selected defects. Data images of each defect type with the corresponding open window around the defect were created for the phase bumps and edge bumps using Flying Cats Graphics, as shown in FIGS. 8 and 9, respectively.

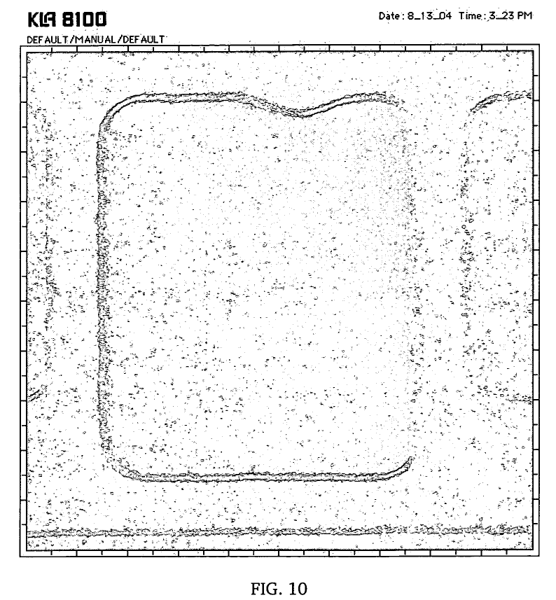

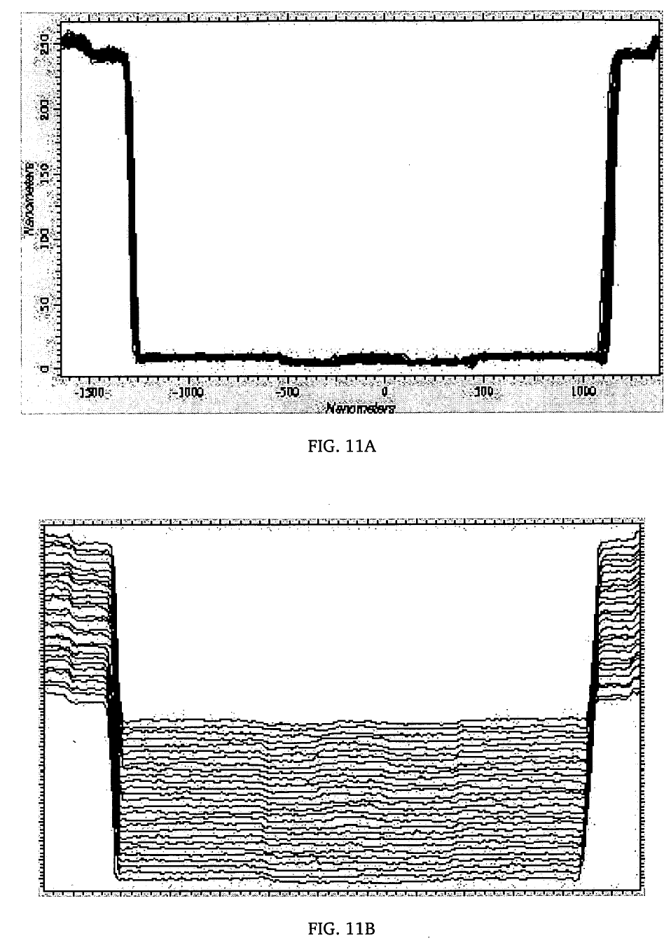

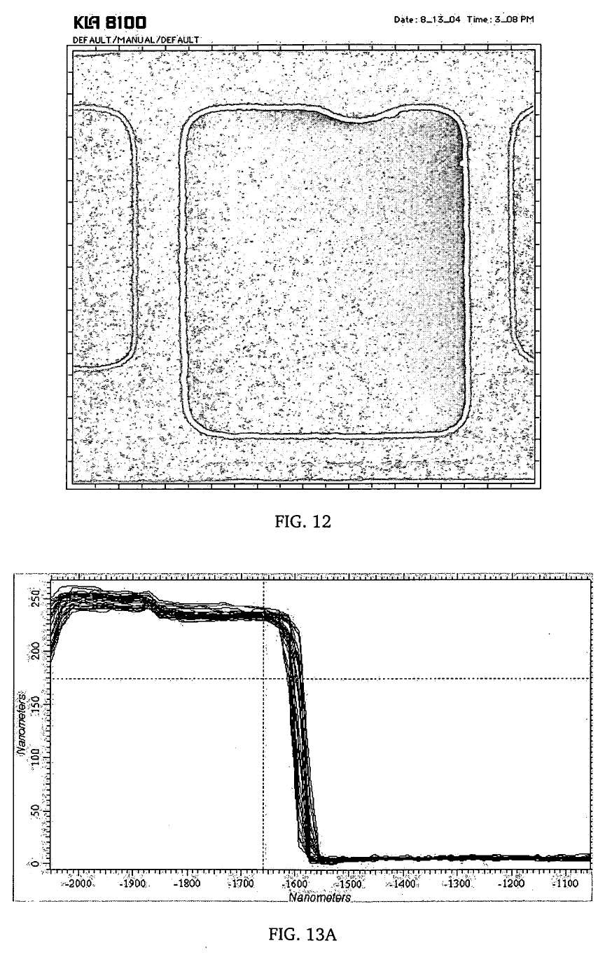

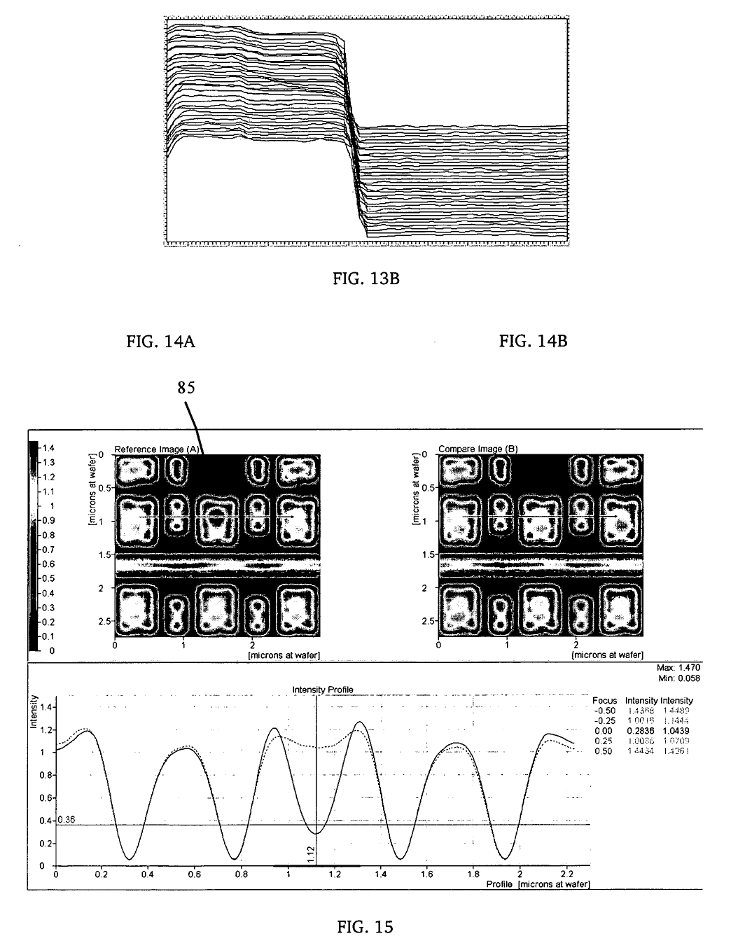

After exposure, the aaPSM was subjected to the same etching technique described above, thereby removing the defect without further etching the unexposed portions of the aaPSM. The aaPSM was then stripped of the remaining photoresist and cleaned. Thereafter, SEM and SNP scans were performed on each location where the defect was removed. Referring to the SEM and SNP images of FIGS. 10, 11A and 11B, respectively, the phase bump defect was successfully removed from the aaPSM. As shown in FIGS. 11A and 11B, this process created a negligible divot in the substantially transparent etch stop layer which was less than 3%. Similarly, as shown in FIGS. 12, 13A and 13B, respectively, the edge bump defect was successfully removed with a negligible divot resulting in the substantially transparent etch stop layer.

An aerial image analysis was performed on the repaired aaPSM using a Zeiss AIMSfab 193 nm system and compared to an aerial image of the aaPSM taken before the defect was removed, as shown in FIGS. 14A, 14B and 15. Illumination conditions were set to an NA=0.80 and sigma=0.30 at 193 nm wavelength. Referring to the intensity profiles shown in FIG. 15, the dashed lines show the intensity profile of the aaPSM before the defects were removed and the solid lines show the intensity profile of the aaPSM after the defects were removed. At best focus, the results clearly show a complete recovery of intensity in the defective region after repair was performed. Thus, if the defects were not removed from the aaPSM, then a post 85 would be printed at the wafer level, as shown in the aerial image of the aaPSM FIG. 14A. However, after removal of the defect, the integrity of the 180° phase shift region was enhanced to a non-defective condition, with no post or other ill effects printing on the wafer, as shown in the aerial image of the aaPSM of FIG. 14B, which was taken after the defect was removed.

Although this experiment did not account for the loss of anti-reflective coating on the chrome layer of the aaPSM in repairing the defects, there was some extra loss of AR as shown on the left edge of the SEM image in FIG. 12. However, this result is inconsequential since the stray light in the stepper has been minimized to minimize image degradation at the wafer. In addition, the mask is patterned with the mask pattern facing down toward the wafer and all radiation is transferred through the mask where the absorber (e.g., Cr) does not allow for added light to penetrate through the lost AR area. This problem can be minimized by considering the overlay of the second write tool.

### Example 2

A second experiment was performed to show the etch performance of a substantially transparent etch stop layer. Separate defects were selected; in this case a 180° edge phase bump defect, and the same process as described above was performed, except the etch time for the repair was modified. In this regard, the etch rate was increased to an equivalent of 450° of overetch. The specific etch rates and selectivity of SiO₂ and the transparent etch stop layer were as follows:

| | | Transparent Etch |
|---|---|---|
| | Substrate | Stop Layer |
| Etch Rate in Quartz Etch [A/sec] | 7.00 | 0.22 |
| Selectivity | 1:1 | 32:1 |
| Phase Error Etch Rate [deg/sec] | 0.7299 | 0.0178 |
| Time to Etch A Degree [sec/deg] | 1.37 | 55.91 |
| Effective Selectivity | 1:1 | 41:1 |

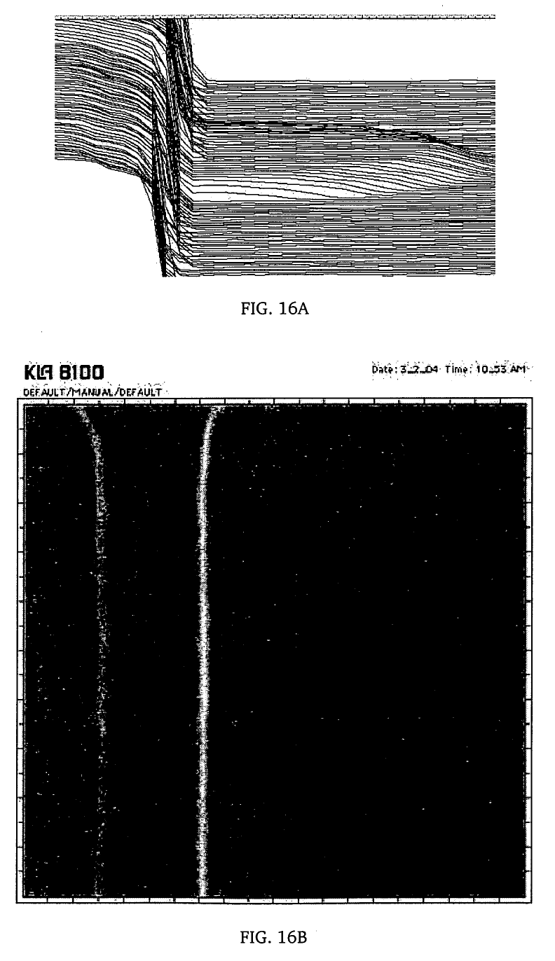

Even with this extreme amount of overetch, the resulting phase defect induced from the etch was ˜20°, as shown in the SNP and SEM images of FIGS. 16A and 16B. This is well below today's defect capture specifications. The index of refraction of the transparent etch stop layer is such that it requires more of the substantially transparent etch stop layer material to be removed to induce the acceptable phase shift of SiO₂.

As observed in the above experiments, defects can be successfully removed from a substantially transparent etch stop layer using method and system of the present invention. Unlike the prior art, no additional equipment (e.g., a mechanical removal tool or FIB tool) is needed to remove defects as the same lithography tools and etching techniques used to process the aaPSM are used. As a result, the cost of repairing defects is reduced and the problems associated with the prior art methods are minimized.

Additionally, the present invention is directed to a method for manufacturing a semiconductor comprising the steps of: interposing a processed photomask (which has had at least one defect removed in accordance with the system and method of the present invention) between a semiconductor wafer and an energy source. The method further comprises the steps of generating energy in the energy source; transmitting the generated energy through the first and second set of at least one light transmitting openings; and etching an image on the semiconductor wafer corresponding to a pattern formed by the first and second set of at least one light transmitting openings.

Now that the preferred embodiments of the present invention have been shown and described in detail, various modifications and improvements thereon will become readily apparent to those skilled in the art. For example, the etch stop layer of the present invention may be used in a wide variety of photomasks. Further, the present invention is not limited to the precise processing steps described herein. In this regard, the aaPSM or other photomasks of the present invention may be made with fewer or more processing steps, depending upon the equipment used and needs of the photomask maker. Further, the method of the present invention may also, for example, form all the unetched regions 40 in a series of processing steps, and form the etched regions 45 in a second series of processing steps. Similarly, the present invention is not limited to photomasks which have only one pattern layer and one etch stop layer associated with the pattern layer, but may apply to photomasks that have more than one pattern to be formed therein, as long as there is a corresponding etch stop layer underlying each layer or set of layers in which each unique pattern is to be formed. Thus, the present embodiments are therefore to be considered in all respects as illustrative and not restrictive, the scope of the invention being indicated by the appended claims, and all changes that come within the meaning and range of equivalency of the claims are therefore intended to be embraced therein.

What is claimed is:

1. A method for repairing a processed photomask comprising the steps of:
identifying at least one defect in a processed photomask which comprises a first layer having a pattern formed therein, an etch stop layer underlying said first layer and a substantially transparent substrate underlying said etch stop later;
generating instructions for a lithography tool to isolate said defect for removal;
depositing a photoresist layer on said processed photomask;
exposing and developing said photoresist in accordance with said instructions to form an open window in said photoresist around said defect; and
removing said defect from said processed photomask.

2. The method of claim 1, wherein said photomask is a binary photomask, and said first layer is an opaque layer.

3. The method of claim 2, wherein said opaque layer is comprised of chrome.

4. The method of claim 1, wherein said photomask is a binary photomask, and said first layer is comprised of an opaque layer and an antireflective layer.

5. The method of claim 4, wherein said opaque layer is comprised of chrome and said antireflective layer is comprised of chrome oxide or chrome oxy nitride.

6. The method of claim 1, wherein said photomask is an embedded attenuated phase shift mask, and said first layer is comprised of a phase shifting layer.

7. The method of claim 6, wherein said phase shifting layer is comprised of MoSi, TaSiO, or TaSiON.

8. The method of claim 1, wherein said etch stop layer is comprised of a substantially transparent etch stop layer.

9. The method of claim 1, wherein said etch stop layer is comprised of one or more of the following: MgFₓ, MgF₂, AlₓO_{y}, Al₂O₃, AlN, AlF, CaF, LiF, SiO₂, SiₓN_{y}, materials including chromium or other material, such as, CrN, CrC, CrO, Ta, TaN, TaNO, TaO, Ta₂O₅, Y₂O₃, ZrO, W (and its oxides), and Mg (and its oxides), as well as a metal or metal based layer, like Ta and Ti.

10. The method of claim 1, wherein said step of identifying at least one defect further comprises the step of generating an inspection file using inspection equipment.

11. The method of claim 10, wherein said inspection file comprises coordinate and size information for said at least one defect.

12. The method of claim 1, wherein said instructions comprise jobdeck instructions.

13. The method of claim 12, wherein said jobdeck instructions specify size and location of said at least one defect and comprise instructions for creating an open window around said at least one defect in a photoresist layer.

14. The method of claim 1, wherein said defect is removed from a partially processed photomask.

15. The method of claim 1, wherein said defect is removed from a fully processed photomask.

16. The method of claim 1, wherein said at least one defect is a 180° phase bump defect.

17. The method of claim 1, wherein said at least one defect is a 180° edge phase bump defect.

18. The method of claim 1, wherein said at least one defect is removed by dry etching.

19. The method of claim 1, wherein said at least one defect is removed by wet etching.

20. A computer system for processing instructions to repair at least one defect in a photomask, wherein said system comprises a computer readable medium capable of performing the following method:
generating jobdeck instructions for isolating at least one defect in a processed photomask, wherein said jobdeck instructions comprise:
the size and coordinates of at least one previously identified defect in said processed photomask; and
instructions which are capable of directing an exposure tool to develop an open window in a photoresist layer so as to surround said at least one defect.

21. The computer system of claim 20, wherein said at least one defect is removed from a fully processed photomask.

22. The computer system of claim 20, wherein said at least one defect is removed from a partially processed photomask.

23. The computer system of claim 20, wherein said at least one defect is a 180° phase bump defect.

24. The computer system of claim 20, wherein said at least one defect is a 180° edge phase bump defect.

25. A processor readable storage medium containing processor readable code for programming a processor to perform a method comprising the steps of:
identifying at least one defect in a processed photomask which comprises a first layer having a pattern formed therein, an etch stop layer underlying said first layer and a substantially transparent substrate underlying said etch stop later;
generating instructions for a lithography tool to isolate said defect for removal;
depositing a photoresist layer on said processed photomask;
exposing and developing said photoresist in accordance with said instructions to form an open window in said photoresist around said defect; and
removing said defect from said processed photomask.

26. A method for manufacturing a semiconductor comprising the steps of:
identifying at least one defect in a processed photomask which comprises a first layer having a pattern formed therein, an etch stop layer underlying said first layer and a substantially transparent substrate underlying said etch stop later;
generating instructions for a lithography tool to isolate said defect for removal;
depositing a photoresist layer on said processed photomask;
exposing and developing said photoresist in accordance with said instructions to form an open window in said photoresist around said defect;
removing said defect from said processed photomask;
interposing the processed photomask between a semiconductor wafer and an energy source;
transmitting energy generated by the energy source through the processed photomask to form an image on the semiconductor wafer; and
etching the semiconductor wafer using the image formed on the semiconductor wafer.
